(19) United States
(12) Patent Application Publication
(10) Pub. No.: US 2003/0048129 A1
(43) Pub. Date: Mar. 13, 2003

(54) Time varying filter with zero and/or pole migration

(76) Inventors: Arthur Sheiman, Great Neck, NY (US); Saimanohora Alapati, Budd Lake, NJ (US); William Tiso, Sparta, NJ (US); Louis Francz, Westfield, NJ (US)

Correspondence Address: KAPLAN & GILMAN , L.L.P., 900NROUTE 9 NORTH, WOODBRIDGE, NJ, 07095, US

(21) Appl. No.: 09/966,802

(22) Filed: Sep. 28, 2001

Related U.S. Application Data
(60) Provisional application No. 60/317,802, filed on Sep. 7, 2001.

(51) Int. Cl. H03B 1/00

(52) U.S. Cl. 327/551

(57) ABSTRACT

A method and apparatus for time varying filtering of an audio signal without introducing audible artifacts is presented. The method comprises filtering a segment of the signal using a given filter, and then disengaging the filter in a sequence of graduated steps at the end of the segment. To then filter the next segment of the input signal with a different filter, the new filter is gradually engaged in a sequence of steps at the beginning of such next segment of the input signal. The remainder of the signal in the segment is filtered with the fully engaged filter, until the end of the segment, where it is gradually disengaged, as was the prior filter. The method of switching filters by gradually disengaging a given filter at the end of signal segments and gradually engaging the next filter at the beginning of the next segment is repeated until the entire input signal has been processed. Such method obviates audible artifacts in the filtered signal, while enabling the time varying filtering of an input signal.

In a preferred embodiment, once disengaged, a filter is removed so as to decrease processor usage.

### CROSS REFERENCE TO RELATED APPLICATIONS

This application claims the benefit of U.S. Provisional Patent Application No. 60/317,802, filed on Sep. 7, 2001.

### TECHNICAL FIELD

This invention relates to signal processing, and more particularly, to an improved technique for varying a filter used to process a given audio signal, so as to remove audible artifacts due to such filter variance and thus improve audio quality.

### BACKGROUND OF THE INVENTION

In digital signal processing applications, such as filtering of audio signals to improve audio quality, the particular filter needed to optimally filter a given input signal often varies over the course of the input signal. Thus, pole and zero locations of the various filters used with the various segments of the input signal will in general be different. Simply switching from one implemented filter to another during processing presents a problem. The filter switch results in an audio artifact, sometimes described as a “click”. The click is both audible and annoying to the user.

For example, suppose in a dictation application the original dictator, dictates a long speech. His environment is such that there is background noise which changes over the course of the dictation. Suppose an airplane flies overhead at one moment, a siren blares in the background at another, a buzzer or bell due to some maintenance function at the dictator's location goes off in a third. Such background sounds are undesirable noise relative to the information content of the dictated speech. Optimally this background noise should be deleted. In the simple case where the noise is an unwanted spectral line in the frequency characterization of the input signal, for example, a notch filter can be used to suppress such an unwanted tone. However, as stated above, if the frequency of the unwanted spectral tone, or some combination of unwanted tones, varies over different portions of the input audio signal, different filters must be used. Hence the idea of time varying filtering.

A filter in general will be desired for one segment of an input signal, but for the other segments will not be desired. Thus, filters must be switched in and out over the duration of the input signal. Alternatively, the various filters could be suppressed by switching in a bypass filter (which would waste computing resources as the “old” filters and their bypass filters accumulate, and each one continues to have its filtering implemented by the system), or the once useful filter can simply be left in place, and continue to filter segments it is useless on. In conventional techniques for the filtering of audio signals, there is really no other alternative. Either (a) a filter is switched in and out, or suppressed by a bypass filter, or (b) a filter is left in place. If the filter is switched abruptly in and out, or a bypass filter is switched in, audible artifacts are generated. If a filter is kept continually in place the recording quality is reduced during the portions of the recording session when the unwanted tone or tones, which that particular filter was designed to remove, are not present. What is desired, therefore, is a means of implementing time varying filtering seamlessly and in a manner inaudible to the user.

It is an object of the present invention to solve the above-described problems inherent in the art, and implement a clickless, or inaudible, method of inserting and removing a filter, or other digital signal processing operator.

### BRIEF DESCRIPTION OF THE DRAWINGS

FIG. 1 is a z-plane diagram depicting an engaged filter according to the present invention;

FIG. 2 is a z-plane diagram depicting the filter of FIG. 1 after zero migration according to the present invention;

FIG. 3 is a z-plane diagram depicting migration of poles and zeros to the origin according to one embodiment of the present invention;

FIG. 4 is a z-plane diagram depicting a second engaged filter according to the present invention;

FIG. 5 is a z-plane diagram depicting the filter of FIG. 4 after zero migration according to the present invention; and

FIG. 6 is a state machine diagram indicating operational flow according to the present invention.

### DETAILED DESCRIPTION OF THE PREFERRED EMBODIMENT

The idea of the present invention is a simple one. It is a clickless, i.e. without audible artifact, method of inserting and removing a filter by gradually migrating the coefficients of the filter from their original values to values wherein the filter has no effect. Conversely, the method in audibly switching on the filter is accomplished by gradually changing the coefficients of such filter from values wherein the filter has no effect to their final values where the filter has the desired effect.

For purposes of illustration, the invention will be illustrated by the insertion and removal of a notch filter, or the switching on and off of such notch filter. Frequency domain analysis will be utilized to illustrate the filters and their engagement and disengagement. Thus, a filter will be illustrated by the locus of its poles and zeros in the z-plane. The changing of the coefficients of the filter from an active to an inactive configuration will be illustrated by migrating the poles and zeros of the notch filter from one locus of positions in the z-plane to another locus of positions. It is understood that the invention can be implemented using any alternative method of visualizing filters, both digital and continuous, and thus the example of a notch filter and the herein described embodiment utilizing the z-plane are intended solely for illustrative purposes and are in no way intended to limit the invention or its various embodiments.

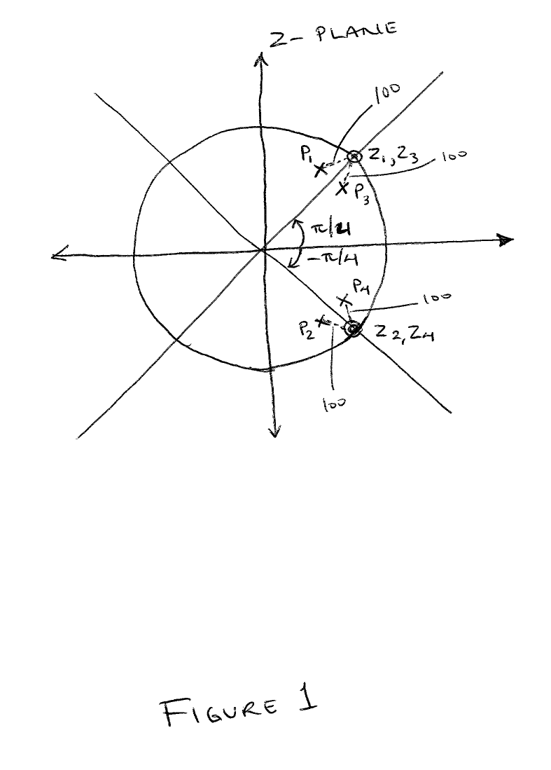

FIG. 1 depicts a fourth order notch filter in the z-plane. As can be seen, there are two complex conjugate pole pairs comprising P1 and P3 in the first quadrant, and their corresponding poles P2 and P4 in the fourth quadrant. As well, there are two zeros collocated at points Z1, Z3 in the first quadrant and Z2, Z4 in the fourth quadrant. This notch filter removes the frequency or unwanted spectral line at π/4 radians (i.e., Fs/8 Hz, where Fs is the sampling frequency). This configuration of the poles and zeros will filter out the frequency of π/4 radians (i.e., Fs/8 Hz). In order to disable this filter, i.e., change the pole and zero locations so that it has no effect whatsoever, is a simple matter. All that needs to be done is to migrate the zeros from their location on the unit circle at ±π/4 (i.e., ±-Fs/8 Hz) to the locations of the poles, such that there remain four points in the z-plane, each with a pole and a canceling zero. For this to be done abruptly, it would create an audible artifact in an audio signal, and some type of anomaly in a different signal type. The method of invention is to do it gradually, in a series of intermediate steps.

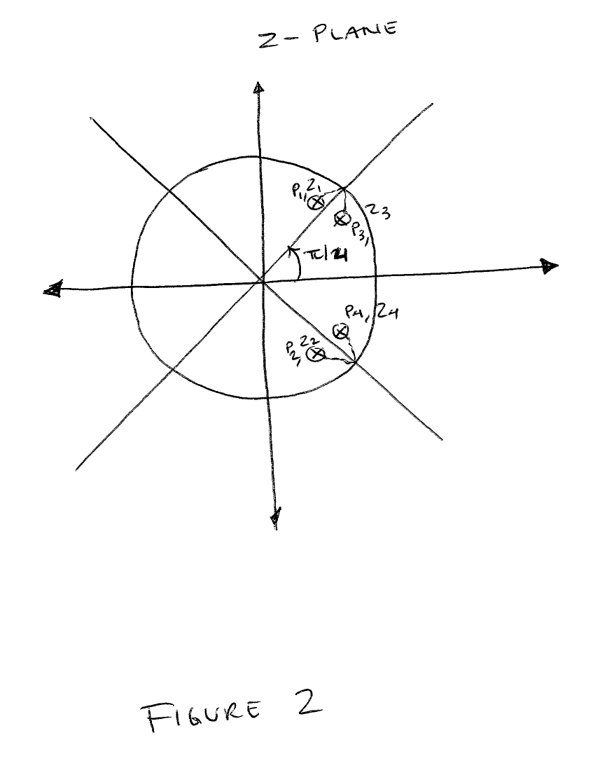

The more gradually the filter is disengaged the larger the segment of the input signal that is involved. Conversely the less gradually, or the more quickly, that the filter is disengaged, fewer samples will be involved. The number of samples per step in the migration of the zeros to the pole locations in general is found empirically for each filter and each signal in each general type of input signal. For the depicted embodiment shown in FIG. 1, the zeros are migrated to the pole locations in 300 intermediate steps, with one input sample per step. Thus, for each subsequent sample, each zero is moved to a different intermediate location until it reaches its corresponding pole. Should a more gradual (or abrupt) disengagement be desired the number of steps could be increased (or decreased), and thus the incremental change of coefficient values from step to step decreased (or increased). As well, numerous samples could be processed at each intermediate filter step as opposed to the one sample per step implementation. FIG. 2 depicts the completely disengaged notch filter showing the four zeros each colocational with one of the poles. FIG. 2 therefore depicts points P1, P2, P3, and P4 where at each such point there is a pole and a zero. These four locations correlate exactly to the original pole locations P1, P2, P3 and P4, respectively, depicted in FIG. 1.

The locus of the poles and zeros depicted in FIG. 2 results in a filter which has no effect, and is thus wholly disengaged.

Once the poles and zeros are colocational, although the effect of the filter is neutralized, since the filter is still operating—although with no net effect—extra mathematical operations are still being performed. These operations cause reduced numerical accuracy and increased processor workload, expressed in Millions of Instructions per Second, or “MIPS.” Thus, in one embodiment of the invention, after the state depicted in FIG. 2 has been reached, the pole/zero pairs comprising the now neutralized filter are removed. This may be done in two ways. The filter can simply be removed, or bypassed, after the colocational points have been reached. Alternatively, the colocational points can be migrated to the origin. Once at the origin, the filter can be abruptly removed without any artifacts. In either case, removal of the filter reduces the MIPS usage, which may be of great utility in dynamic systems, which allocate MIPS adaptively, such as multichannel systems.

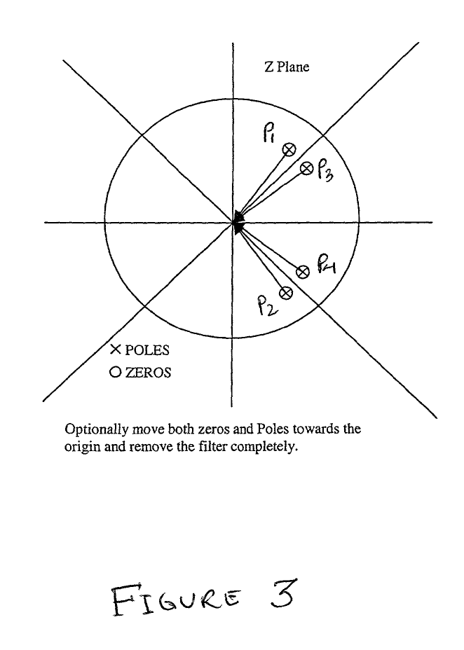

FIG. 3 depicts the migration to the origin method, showing the four pole/zero colocational points, identical to those depicted in FIG. 2, now being migrated to the origin for removal of the entire filter upon reaching the origin. During the entire migration of the pole/zero pairs from their final locations, as depicted in FIG. 2, to the origin, the filter remains neutralized and has no effect on the signal.

In general, the number of steps used in the migration of the zeros to the poles, or vice versa, as the case may be, in neutralizing a filter, will be determined empirically by the user. As well, the same determination as to the number of steps will be made by the user if after neutralization the colocational points are migrated to the origin, and from there the filter bypassed. The operational tradeoffs in determining the number of such steps are speed of removal of an unwanted filter vs. tolerable audible artifacts.

As well, whether to bypass the filter, as in the above described embodiment, or simply to leave it operating with no net effect will depend upon the application. In some applications, it may not be necessary to turn off the filter after neutralization. Although this can cause reduced accuracy and consumes more MIPS, in some applications MIPS availability is static, designed for the worst case MIPS requirements. Thus, there is no benefit realized by turning off the filter. Accuracy is also not always an issue, as real-world noise and distortion in a given environment can greatly outweigh the precision of the digital signal processor (“DSP”). In such applications, simplicity and less control code are more important than wasting already statically allocated MIPS.

On the other hand, in an application where the DSP been designed to operate on a large number of channels, and if it had software to take advantage of the statistical nature of the application (a resource manager and a way to degrade slowly rather than hard fail), turning off the filter can be a very good idea. Turning off the filter may be very important in other applications, too.

The theoretical and practical issues involved in turning off the filter after neutralization are as follows. For simplicity, consider a first order system with a single zero at z=b and a single pole at z=a:H(z)=(z-b)/(z-a). It is assumed, for illustration purposes, that the zero is migrated and the pole left fixed (as would be the normal case with a notch filter, as described above). Assume further, that in this illustration the notch occurs at a frequency of 0. The time domain equation is: y[k]=a*y[k−1]+u[k]−b*u[k−1]. Again, for illustrative purposes only, consider that the zero moved instantly at some point in time from b=1 to b=a. Now, say that at some subsequent arbitrary time, the filter is to be turned off, i.e., y[k]=u[k]. In theory, if the filter has been excited (as would be the normal case for a non-zero input signal), a*y[k-1] will not equal a*u[k−1]. The two are only equal after the filter transient has settled. If the coincident zero/pole pair is migrated toward zero, this is effectively forcing the terms a*y[k−1] and a*u[k−1] to zero. Once they are zero, the filter can be bypassed. This describes the theoretical model for an abrupt change in the zero from b=1 to b=a.

Practically, however, the case would generally be different. The zero would generally be slowly migrated to the pole position. If this occurs slowly enough, then the transient would most likely (except for a nearly unstable filter) be decayed to a small value. Thus, turning off the filter at the colocational pole zero points would result in little or no audible glitch, and would be the preferred solution. If there was an audible glitch, what could be done is to simply wait a bit (this will allow the transient to decay) and then bypass the filter. It is noted that migrating the pole and zeros toward the origin makes the filter more stable, and thus speeds the decay of the transients.

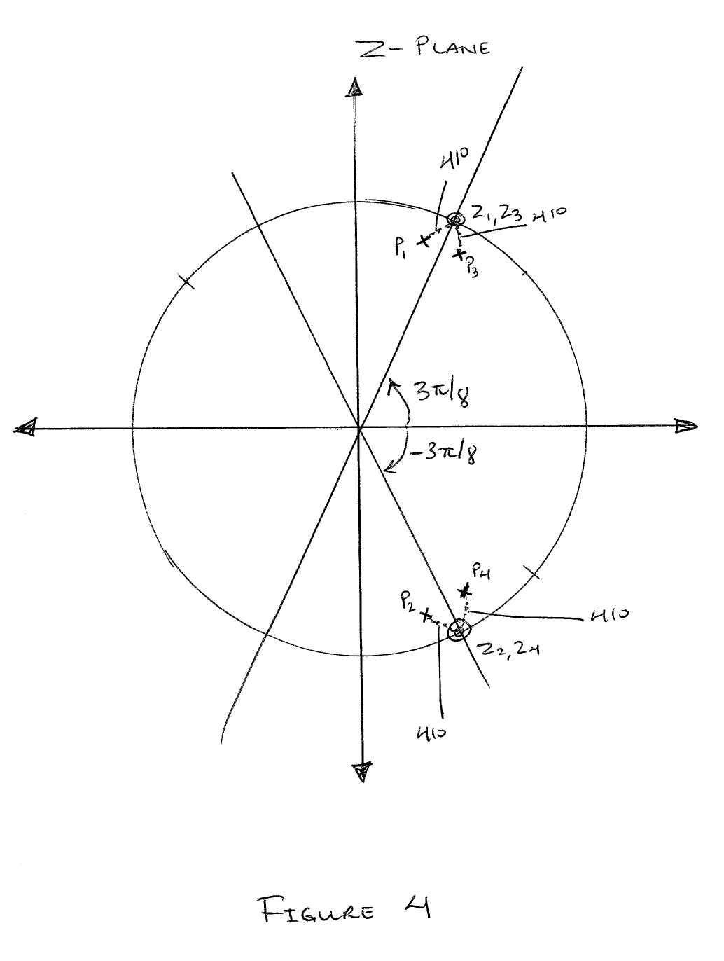

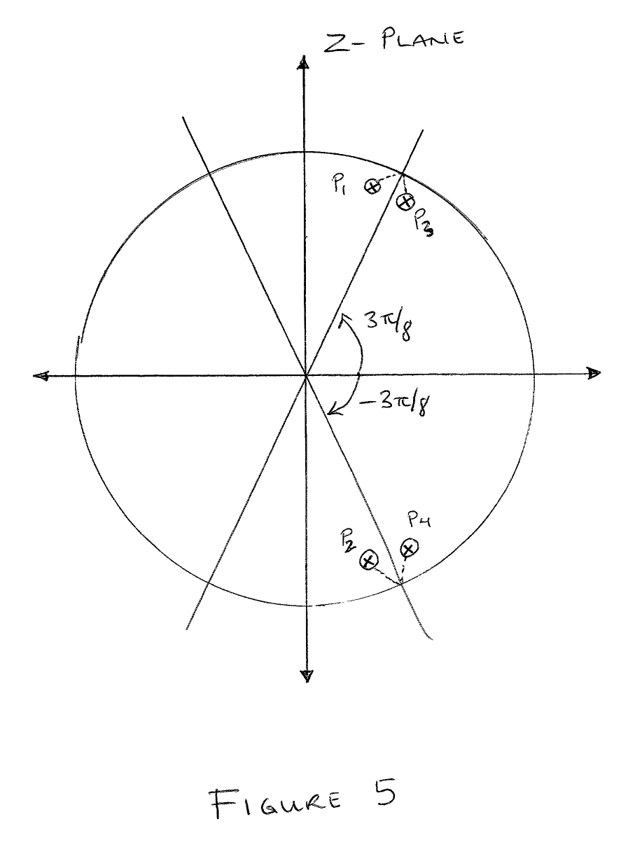

Thus far, the gradual, and thus inaudible, disengaging of a filter has been described. The inverse of neutralizing a filter is engaging, or enabling, a filter. For purposes of illustration, it is assumed that the unwanted spectral line in the signal frequency spectrum, or unwanted tone, at π/4 (i.e., Fs/8 Hz) which was bothersome in the first part of the signal (as described above) is no longer present in a second part of the signal. However, the second part of the signal has an annoying unwanted spectral line at 3π/8 radians (i.e. Fs*3/16 Hz). Thus, to suppress the unwanted spectral line at 3π/8 radians (i.e., Fs*3/16 Hz), the filter depicted in FIG. 4 is used. Once again, this is a fourth order notch filter designed to remove the unwanted tone in the second segment of the input signal, now at 3π/8 (i.e., Fs*3/16 Hz). As can be seen, two complex conjugate pairs of poles and two colocational pairs of zeros at each of ±3π/8 (i.e., ±Fs*3/16 Hz) comprise the filter. For the reasons discussed above, this filter can simply not just be turned on but it needs to be gradually engaged so as to avoid audible artifacts in the filtered, or output signal. Utilizing exactly the inverse of the neutralizing method of the filter depicted in FIGS. 1 and 2, to engage the filter of FIG. 4, there is first implemented the filter in FIG. 5 which is nothing more than the notch filter depicted in FIG. 4 with the zeros now colocational with the four poles, thus being a neutralized filter. To engage this filter, the zeros are migrated over a series of intermediate locations, along the dotted lines 410, to their final positions on the unit circle. In all the figures, the zeros are migrated, whether from the unit circle, or to the unit circle, along the shortest line in the z-plane between their original locations and their final locations.

In general, a filter will have various poles and zeros, and either can be migrated to the other to reach a destination point of each pole with its corresponding zero. The migration should be such as to most efficiently disengage the filter. Thus, the shortest path between the poles and zeros should be utilized for the migration. The particular manner in which the poles and zeros are migrated to each other can be optimized for the filter being used, the characteristics of the noise being filtered, as well as the characteristics of the input signal being operated upon. Thus, in the filter depicted in FIG. 1, since any migration of the poles toward the zeros would tend to increase the effect of the poles, and leave the zeros at their full influence, the zeros are migrated towards the poles, along the shortest path between them, as indicated by the dotted lines in FIG. 1.

In this embodiment each pole zero pair, or other final configuration of the filter, will then be removed, to reduce wasted computational resources. As described above, generally the filter will be bypassed after neutralization, but may, if necessary, have the colocational pole zero pairs first migrated to the origin.

FIG. 6 depicts a state machine diagram for the example filter depicted in FIG. 1, where the filter is bypassed, but never removed (thus neither removal of the filter from the final configuration shown in FIG. 3, nor the removal of the filter from the configuration of FIG. 2, occurs in this example system). The binary variable NotchRequest is the input to the state machine. As described above, each particular application, as well as the subjective perception of the users interacting with the output signal, will determine the minimum steps needed to fall below the threshold of perceptible artifacts (auditory or otherwise, as determined by the signal being processed). Such step numbers can be empirically found with relative simplicity. The number of steps used is the variable “STEPS” to a coefficient calculation function, labeled Calc Coeff in FIG. 6. In the system of FIG. 6, the Calc Coeff function is determined by parameterizing the migration paths, and STEPS=300. Consider the migration of the zeros of the depicted fourth order notch filter of FIG. 1. In this case, for a notch filter, the poles and zeros align on straight lines in the z-plane, which are the dotted lines 100 in FIG. 1. The coefficients can be calculated in real time, or if the filter used in the system is known a priori, as well as the desired step number, the various coefficients for each step can be stored in a lookup table, moving thereby the complex high MIPS calculations to non-real-time at the expense of a small to moderate table.

In FIG. 6 the state 600 “Notch Bypass”, is that where no filter is operating, and the poles and zeros are colocational, as in FIG. 2. In state 620 “Notch ON” the filter is fully engaged. States 610 and 630 represent the migration stages “Migrate Notch IN” and “Migrate Notch OUT.” In state 610 the filter is migrated from a neutralized state to the fully engaged state, via the intermediate steps. In state 630 filter is migrated from a fully engaged state, to the neutralized state, via the intermediate steps. The number of intermediate steps is controlled by the variable “STEPS.”

The system moves from state 600 to state 610, along path 601, when Notch Request is set to ON. In state 610 the filter is migrated from being bypassed (i.e., the poles and zeros are colocational), as depicted in FIG. 2, through the 300 intermediate steps, to being fully implemented, as depicted in FIG. 1. Once the final step has been reached, i.e., STEPS=300 in the illustrative system of FIG. 6, the state moves, along path 611, to state 620,, “Notch ON.” From there a Notch Request=OFF will move the system, along path 621, to state 630, where the reverse happens, and the poles and zeros in the configuration of FIG. 1 now migrate to the configuration of FIG. 2, via the 300 intermediate steps. When, in state 630, STEPS=300, the filter is totally migrated OUT, and the system moves, along path 631, to state 600.

As well, if in the middle of a filter migration one way or the other the Notch Request value changes, the system will move from state 610 to state 630 or vice versa. With reference to FIG. 6, if in state 630, where the filter is migrating OUT due to a Notch Request=OFF signal, Notch Request switches to ON, the system moves, along path 632, to state 610, and migrates the filter back IN, beginning from whatever the value of STEP was when the Notch Request signal changed from OFF to ON. Conversely, if in the middle of a migration IN, where the system is in state 610, Notch Request goes to OFF, the system moves, along path 612 to state 630, and the migration OUT proceeds from whatever the value of STEP was in state 610.

Although the invention has been illustrated via the z-plane depiction of filters, the actual coefficients used to operate upon the input signal are calculated from these pole and zero locations, and could be calculated from any equivalent representation of a filter, whether time domain or frequency domain. As described above, the entire invention may be implemented using a computer or other data processing devices, with the appropriately written software. The various functionalities of the invention may be implemented using hardware, software, or combinations of both, resulting in various permutations of the presently depicted embodiment.

While the foregoing describes one embodiment of the invention, it will be appreciated by those of skill in the art that various modifications and additions may be made. Such additions and modifications would include, without limitation, disengaging/engaging any filter in the general sense, i.e. any signal processing operator, operating on either discrete or continuous inputs, irrelevant as to how the given filter is depicted, being z-plane, s-plane, time domain, etc.. Such modifications are intended to be covered by the following claims.

What is claimed is:

1. A method of time varying filtering, comprising:
a. filtering a segment of a signal using a filter; and
b. disengaging the filter in a sequence of graduated steps at the end of the segment; and
c. repeating steps a and b until all segments have been filtered.

2. The method of claim 1, where a given filter is disengaged by changing the coefficients from their regular values for the filter to values reflecting a gain of unity and no phase delay.

3. The method of claim 2, where each filter is disengaged in a series of intermediate steps.

4. The method of claim 3, where in each said step the filter has a different set of coefficients.

5. The method of claim 4, where one sample from the input signal is processed during each step.

6. The method of claim 4, where two or more samples from the input signal are processed during each step.

7. A method of time varying filtering, comprising:
a. engaging a filter in a sequence of graduated steps at the beginning of a signal segment;
b. filtering the segment of using the filter; and
c. repeating steps a and b until all segments have been filtered.

8. The method of claim 7, where a given filter is engaged by changing the coefficients from values reflecting a gain of unity and no phase delay to their regular values.

9. The method of claim 8, where each filter is engaged in a series of intermediate steps.

10. The method of claim 9, where in each said step the filter has a different set of coefficients.

11. The method of claim 10, where one sample from the input signal is processed during each step.

12. The method of claim 10, where two or more samples from the input signal are processed during each step.

13. A method of time varying filtering, comprising:
a. engaging a filter in a sequence of graduated steps at the beginning of a signal segment;
b. filtering the segment of using the filter;
c. disengaging the filter in a sequence of graduated steps at the end of a signal segment; and
d. repeating steps a-c until all segments have been filtered.

14. The method of claim 13, where a given filter is engaged by changing the coefficients from values reflecting a gain of unity and no phase delay to their regular values.

15. The method of claim 14, where each filter is engaged in a series of intermediate steps.

16. The method of claim 15, where in each said step the filter has a different set of coefficients.

17. The method of claim 16, where one sample from the input signal is processed during each step.

18. The method of claim 16, where two or more samples from the input signal are processed during each step.

19. An article comprising a computer readable medium having instructions stored thereon which when executed causes:
a. filtering a segment of a signal using a filter;
b. disengaging the filter in a sequence of graduated steps at the end of the segment; and
c. repeating steps a and b until all input signal segments have been filtered.

20. An article comprising a computer readable medium having instructions stored thereon which when executed causes:
a. engaging a filter in a sequence of graduated steps at the beginning of a signal segment;
b. filtering the segment using the filter; and
c. repeating steps a and b until all input signal segments have been filtered.

21. An article comprising a computer readable medium having instructions stored thereon which when executed causes:
a. filtering a segment of a signal using a filter;
b. disengaging the filter in a sequence of graduated steps at the end of the segment;
c. engaging a filter in a sequence of graduated steps at the beginning of the next segment of the signal; and
d. repeating steps a-c until all input signal segments have been filtered.

22. A method, comprising:
inaudibly switching one or more filters on and/or off during processing of an input signal by:
migrating their coefficients from an original set of values to a final set of values through a series of intermediate steps.

23. The method of claim 22, where said filters are:
engaged by changing the coefficients to their regular values for the filter from values reflecting a gain of unity and no phase delay, and disengaged by changing the coefficients from their regular values for the filter to values reflecting a gain of unity and no phase delay.

24. The method of claim 23, where each filter is disengaged or disengaged, as the case may be, in a number of intermediate steps.

25. The method of claim 24, where in each said step the filter has a different set of coefficients.

26. The method of claim 25, where one sample from the input signal is processed during each step.

27. The method of claim 25, where two or more samples from the input signal are processed during each step.

28. Apparatus for time varying filtering, comprising:
a filtering processor, arranged to process a given input signal by implementing an arbitrary filter; and
a coefficient calculator, arranged to calculate:
the co-efficients for the arbitrary filter;
a set of new coefficients for the arbitrary filter, at which the filter is neutralized; and
a series of intermediate co-efficient values between the original filter coefficients and the new coefficients.

29. The apparatus of claim 28, further comprising a memory to store a plurality of filtering coefficients.

30. The method of any of claims 1-6, or of claims 13-18, where a filter is disengaged by migrating its poles to its zeros, or its zeros to its poles.

31. The method of claim 30, where after the migration has been completed, the filter is removed.

32. The method of claim 30, where after the migration has been completed, the colocational poles and zeros are then migrated to the origin via a series of intermediate steps.

33. The method of claim 30, where after the migration has been completed:
the colocational poles and zeros are then migrated to the origin via a series of intermediate steps; and the filter is then removed.
